(19) United States
(12) Patent Application Publication
(10) Pub. No.: US 2014/0116544 A1
(43) Pub. Date: May 1, 2014

(54) Device to Generate a Gas Mixture

(71) Applicant: Dockweiler AG, Neustadt-Glewe (DE)

(72) Inventor: Torsten Köcher, Reinbek (DE)

(73) Assignee: Dockweiler AG, Neustadt-Glewe (DE)

(21) Appl. No.: 14/068,545

(22) Filed: Oct. 31, 2013

(30) Foreign Application Priority Data
Oct. 31, 2012 (DE) 10 2012 021 527.4

(51) Int. Cl. C23C 16/455

(52) U.S. Cl. CPC C23C 16/45512
USPC 137/561 R

(57) ABSTRACT

A device for generating a gas mixture with a ring-cylindrical reaction chamber that is delimited by a cylindrical inner wall and a cylindrical outer wall as well as an annular head section and an annular floor section, wherein the head and floor sections leave free an inner area formed by the inner wall.

### CROSS-REFERENCE TO RELATED APPLICATIONS

This Utility Patent Application claims priority to DE 10 2012 021 527.4, filed on Oct. 31, 2012

### STATEMENT REGARDING FEDERALLY SPONSORED RESEARCH Not applicable.

### BACKGROUND OF THE INVENTION

The present invention relates to a device for generating a gas mixture as for example used in metal organic chemical vapor deposition (MOCVD) in semiconductor engineering.

In technical jargon, such devices are also termed bubblers in which a carrier gas, such as hydrogen and nitrogen, is introduced into a reaction chamber of the bubbler and contacts metal organic components such as trimethyl aluminum (TMA), trimethyl gallium (TMG), triethyl gallium (TEG), trimethyl antimony (TMSb), dimethyl hydrazine (DMHy), trimethyl indium (TMI) and/or cyclopentadienyl magnesium (Cp₂Mg). With a so-called solid bubbler, the metal organic components are present as a solid in the reaction chamber, and the carrier gas is conducted under a given temperature and pressure through the solid in the reaction chamber and absorbs metal organic compounds.

From WO 2005/113857, the entire contents of which is incorporated herein by reference, a solid bubbler is known in which the reaction chamber possesses a number of subchambers through which the carrier gas passes in a serial manner.

From DE 10 2007 024 266 A1, the entire contents of which is incorporated herein by reference, a bubbler is known that is filled with liquid, wherein the evaporation pressure can be set within the reaction chamber by controlling the temperature of the medium to be evaporated. The carrier gas is supplied by means of an L-shaped immersion line at the base of the reaction chamber, and the direction of flow of the carrier gas is directed away from the base of the reaction chamber.

From DE 2004 010 834 U1, the entire contents of which is incorporated herein by reference, a device is known for adjusting the temperature of a material in a cylindrical chamber, wherein compressed air introduced into the chamber is circulated in a circle in a ring.

From DE 37 08 967 A1, the entire contents of which is incorporated herein by reference, a device is known for generating a gas mixture according to the saturation method in which a carrier gas is introduced through an immersion tube into a liquid located in the reaction chamber. A contact-free level sensor is provided for the reaction chamber and controls a dosing device for the liquid in the reaction chamber.

From EP 1 160 355 B1, the entire contents of which is incorporated herein by reference, an evaporator is known that possesses a gas inlet chamber which, at its base, is provided with a porous termination that separates the gas inlet chamber from a gas outlet chamber.

A device to generate a gas mixture is generally introduced into a temperature control device. The temperature control device possesses a medium such as water that is held at a precisely set temperature. Among other things, the temperature in the reaction chamber is precisely set by means of the external temperature control device. The temperature in the reaction chamber is decisive in regard the concentration of metal organic compounds in the exiting gas.

An object of the invention is to provide a device for generating a gas mixture which enables the temperature of the reaction chamber to be precisely controlled using simple means.

### BRIEF SUMMARY OF THE INVENTION

The device according to the invention is provided and intended for generating a gas mixture. In particular, it is a solid bubbler into which a carrier gas is introduced, and a discharge gas is obtained that is enriched with metal organic compounds. The device according to the invention possesses a ring-cylindrical reaction chamber that is delimited by a cylindrical inner wall and a cylindrical outer wall. The reaction chamber is therefore delimited by two cylindrical walls according to the invention. In addition, the device according to the invention possesses an annular head section and an annular floor section by means of which the cylindrical inner wall and cylindrical outer wall are connected to each other. The annular head section and annular floor section leave free an inner area that is formed by the inner wall. The device according to the invention is characterized in that the reaction chamber is delimited by a cylindrical inner wall and a cylindrical outer wall and therefore possesses a large surface facing the surroundings. The interior within the cylindrical inner wall is free and is also not enclosed by the head section and the floor section of the device. If the device according to the invention is introduced into a temperature control device that is filled for example with water, the water therefore flows around the cylindrical outer wall as well as the cylindrical inner wall so that the reaction chamber between the inner wall and outer wall possesses a large contact surface with the temperature-controlled water.

In one preferred development, at least one gas supply pipe is guided through the head section and possesses one or more outlet openings for a gas to be fed into the cylindrical reaction chamber. The supply pipe preferably has an elongated pipe section and an annular distribution section. The annular distribution section runs in a radial direction completely or partially around the inside of the ring-cylindrical reaction chamber. The elongated pipe section of the supply pipe preferably extends in an axial direction with reference to the ring-cylindrical reaction chamber.

For an even discharge of the supplied gas, the angular distribution section is preferably provided with a plurality of outlet openings distributed in a radial direction. It has proven to be advantageous to arrange the outlet openings on a side in the annular subsection facing the floor section. The pipe section and annular distribution section preferably form a right angle relative to each other, wherein the annular distribution section is arranged closer to the floor section than to the head section of the device so that the gas introduced into the reaction chamber travels the longest possible path in the reaction chamber.

In one preferred development of the device according to the invention, a gas discharge pipe is guided through the head section, wherein the gas discharge pipe possesses one or more outlet openings for a gas to be discharged from the ring-cylindrical reaction chamber. The gas discharge pipe preferably possesses a central inlet opening that is arranged closer to the head section than the floor section of the device.

In one useful embodiment, the cylindrical inner wall and cylindrical outer wall are arranged concentrically to each other. The concentric arrangement ensures that the reaction chamber which is formed as a ring cylinder between the inner wall and outer wall possesses a constant thickness in a radial direction.

To enable a very even contact between the inner wall and a temperature-controlled medium, the inner diameter of the annular head section is identical with the inner diameter of the cylindrical wall. Likewise, the inner diameter of the annular floor section corresponds with the inner diameter of the cylindrical wall.

For an even distribution of the gas introduced into the reaction chamber, the floor section preferably has an arched base that curves radially inward from the reaction chamber. Relative to the reaction chamber, the arched base is arched outward in a convex manner.

### BRIEF DESCRIPTION OF THE SEVERAL VIEWS OF THE DRAWINGS

A preferred embodiment of the device according to the invention is further explained with reference to an example. In the figures:

FIG. 1 shows a solid bubbler with its connections in a view from the side,

FIG. 2 shows the solid bubbler from FIG. 1 in a view from above without the connections,

FIG. 3 shows a section along line A-A from FIG. 2,

FIG. 4 shows the section from FIG. 3 without a cylindrical outer wall and floor element,

FIG. 5 shows the gas supply pipe in a view from the side,

FIG. 6 shows the gas supply pipe in a view from below,

FIG. 7 shows a section of the floor section,

FIG. 8 shows a plan view of the floor section, and

FIG. 9 shows a perspective view of the floor section.

### DETAILED DESCRIPTION OF THE INVENTION

While this invention may be embodied in many different forms, there are described in detail herein a specific preferred embodiment of the invention. This description is an exemplification of the principles of the invention and is not intended to limit the invention to the particular embodiment illustrated.

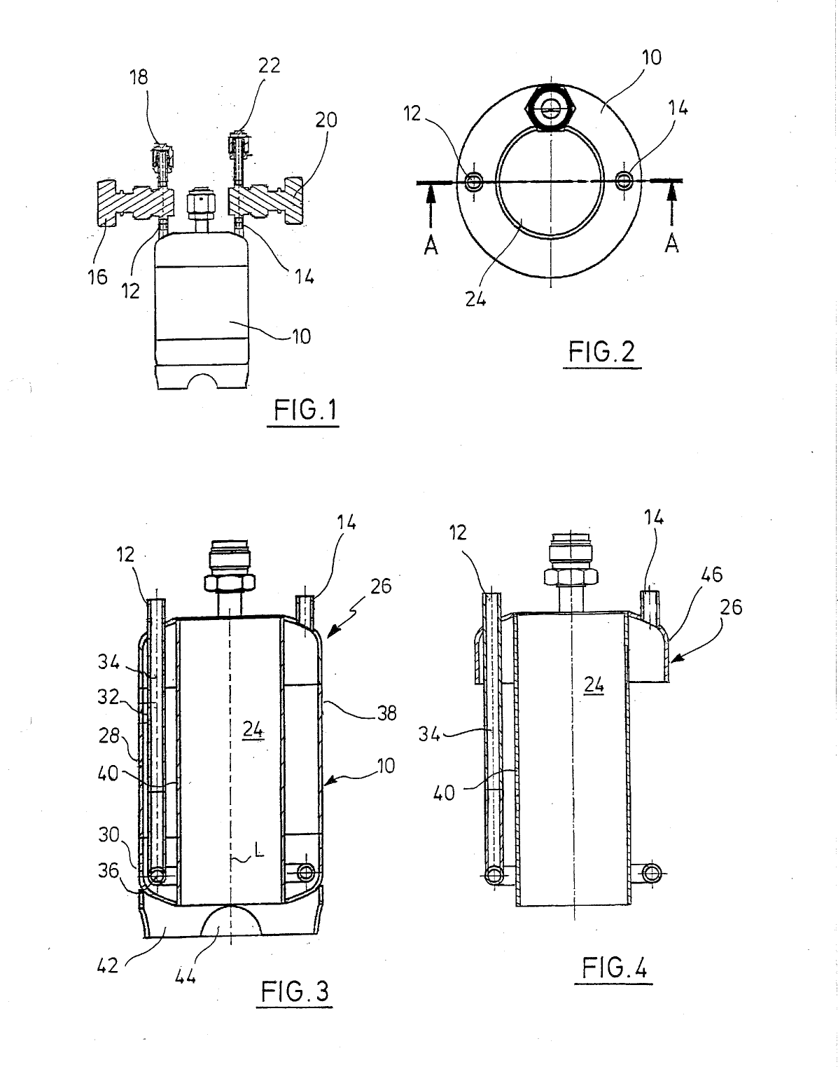

FIG. 1 shows a view of a device for generating a gas mixture in the form of a solid bubbler 10. The solid bubbler 10 possesses a supply line 12 by means of which a carrier gas can be fed into a reaction chamber, and a discharge line 14 by means of which the carrier gas enriched with metal organic compounds can be discharged from the reaction chamber. A schematically portrayed valve 16 is shown on the supply line 12. The inlet line of the valve 16 is closed by means of an end cap 18. To operate the solid bubbler 10, the end cap 18 is removed and connected to a supply line for the carrier gas. The gas discharge line 14 also has a control valve 20 with a discharge line that is closed by means of an end cap 22. When the solid bubbler 10 is operating, the end cap 22 is removed, and the discharge line of the valve 20 is connected to the process controls.

FIG. 2 shows a plan view from above of the solid bubbler 10, wherein the valves are removed from the supply line 12 and discharge line 14. FIG. 2 clearly shows that the solid bubbler 10 possesses an overall ring-cylindrical shape with a cylindrical area 24 that is free. In this case, “ring-cylindrical” means a geometric shape that is enclosed between an interior cylinder and an exterior cylinder. The portrayed exemplary embodiment relates to concentrically arranged circular cylinders that define a ring-cylindrical space with a constant radial extension.

FIG. 3 shows a section of the solid bubbler 10 along line A-A from FIG. 2. FIG. 3 discloses a three-part design of the solid bubbler with a head section 26, a middle cylinder section 28, and a floor section 30. A gas supply line 32 is guided through the head section 26. At its end projecting out of the head section 26, the gas supply line 32 possesses a gas inlet opening 12. The gas supply line 32 possesses an elongated pipe section 34 that extends parallel to the longitudinal axis L and ends in an annular distribution section 36. The annular distribution section 36 makes one complete circuit within the floor section of the solid bubbler and therefore forms a closed circle.

The gas outlet opening 14 is also provided in the head section 26 and possesses a connecting piece which does not extend into the interior of the solid bubbler.

As can be seen in FIG. 3, a cylindrical outer wall 38 is arranged on the outside between the head section 26 and the floor section 30. A cylindrical inner wall 40 is provided on the inside. As can be clearly seen in FIG. 3, the cylindrical inner wall 40 extends in a longitudinal direction to the top end of the head section 26 and to the bottom end of the floor section 30. In contrast, the cylindrical outer wall is designed shorter in an axial direction, and extends from the floor-side end of the head section to the head-side end of the floor section 30.

The floor section 30 possesses a peripheral foot 42 in which a number of cutouts 44 are provided. By means of the cutouts 44, the interior 24 formed by the inner wall 40 is connected to the surroundings in the region of the foot section 30.

The employed design with a cylindrical inner wall extending the entire longitudinal direction is shown again in FIG. 4. FIG. 4 shows the same section as in FIG. 3; however, the cylindrical outer wall 38 and floor section 30 are omitted. In FIG. 4, it can be clearly seen that the inner wall 40 is formed by a cylindrical pipe which is open at the head end and at its floor end. An arched metal plate 46 is placed on the head end of the pipe 40, and it forms the head section 26 with the gas supply pipe and the passage for the gas supply pipe 32.

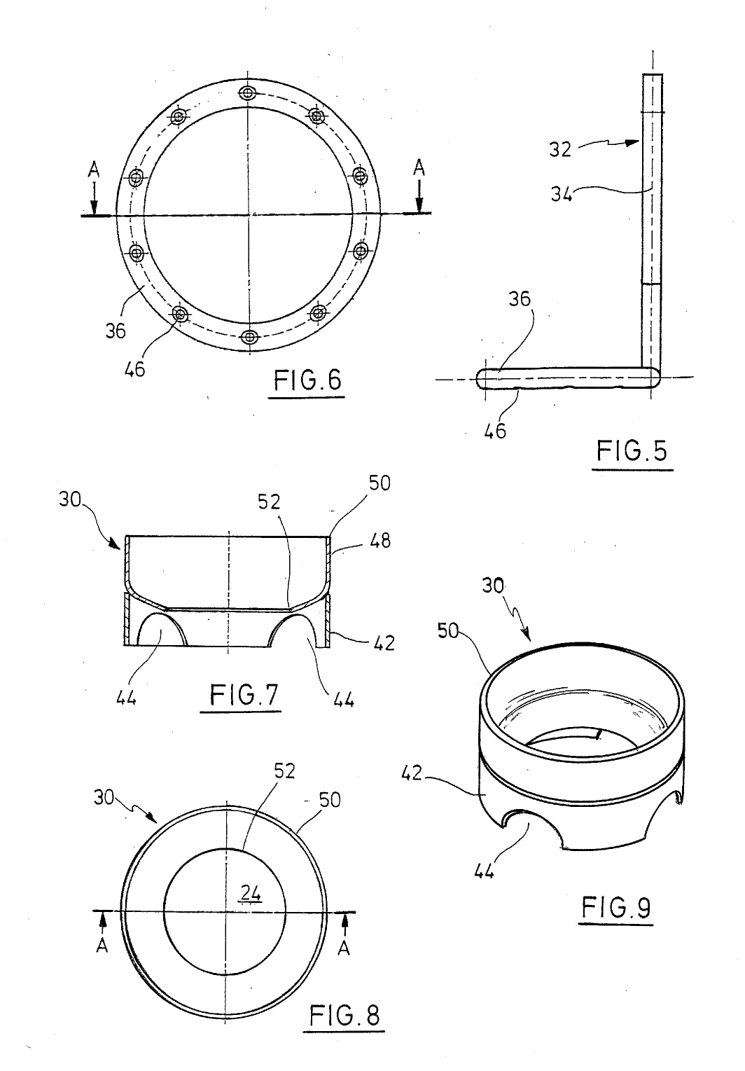

FIG. 5 shows the gas supply pipe 32 with its elongated section 34 and its distribution section 36. The elongated section 34 and the distribution section 36 possess the same pipe diameter, wherein outlet openings 46 are provided in the distribution section 36 on the side facing away from the elongated section 34.

FIG. 6 shows a view of the distribution section 36 from below in which the equidistantly arranged gas outlet openings 46 can be seen. To promote the exit of gas, the gas outlet openings possess a conically expanding bore that narrows toward the interior of the gas distribution pipe 36. The gas distribution pipe 36 is designed as a closed circle.

In the sectional view A-A from FIG. 2 or FIG. 8, FIG. 7 shows the floor section 30. The floor section 30 possesses a cylindrically peripheral foot 42 with cutouts 44. The floor section 30 is formed by a floor plate 48 arched inward. At its edge 50 facing the head end, the floor plate 48 is connected to the cylindrical outer wall 38. With its edge 52 projecting radially inward, the floor plate 48 is connected to, and preferably welded to the cylindrical inner wall 40.

FIG. 8 shows a plan view of the floor element 30 from FIG. 7 in which both edges of the floor plate 48 can be clearly seen. It can also be seen that the edge 52 projecting radially inward delimits the cylindrical interior 24. FIG. 9 shows a corresponding perspective view of the floor section 30.

This completes the description of the preferred and alternate embodiments of the invention. Those skilled in the art may recognize other equivalents to the specific embodiment described herein which equivalents are intended to be encompassed by the claims attached hereto.

### LIST OF REFERENCE NUMBERS

10 Solid bubbler

12 Supply line

14 Discharge line

16 Valve

18 End cap

20 Control valve

22 End cap

24 Cylindrical region

26 Head section

28 Middle cylindrical section

30 Floor section

32 Gas supply pipe

34 Pipe section

36 Distribution section/gas distribution pipe

38 Cylindrical outer wall

40 Cylindrical inner wall

42 Peripheral foot

44 Cut-out

46 Outlet openings

48 Floor panel

50 Edge

52 Inwardly projecting edge

What is claimed is:

1. A device for generating a gas mixture with a ring-cylindrical reaction chamber that is delimited by a cylindrical inner wall and a cylindrical outer wall as well as an annular head section and an annular floor section, wherein the head and floor sections leave free an inner area (24) formed by the inner wall.

2. The device according to claim 1, wherein at least one gas supply pipe (34) is guided through the head section and possesses one or more outlet openings (46) for a gas to be supplied in the ring-cylindrical reaction chamber.

3. The device according to claim 2, wherein at least one supply pipe has an elongated pipe section (34) and an angular distribution section (36), wherein the annular distillation section (36) runs around all or part of the inside of the reaction chamber in a radial direction.

4. The device according to claim 3, wherein the annular distribution section (36) possesses a plurality of outlet openings (46) distributed in a radial direction.

5. The device according to claim 4, wherein the outlet openings (46) are arranged on a side of the annular distribution section (36) facing the floor section.

6. The device according to claim 3, wherein the elongated pipe section and the annular distribution section are at a right angle to each other.

7. The device according to claim 3, wherein the annular distribution section is arranged closer to the floor section than to the head section.

8. The device according to claim 1, wherein a discharge pipe (14) is guided through the head section (26) and has one or more outlet openings for a gas to be discharged from the ring-cylindrical reaction chamber.

9. The device according to claim 8, wherein the gas discharge pipe (14) has a central inlet opening.

10. The device according to claim 8, wherein the inlet opening is arranged closer to the head section than to the floor section.

11. The device according to claim 1, wherein the inner wall (40) and the outer wall (38) are arranged concentrically to each other.

12. The device according to claim 1, wherein the inner diameter of the annular head section corresponds to the inner diameter of the cylindrical inner wall.

13. The device according to claim 1, wherein the inner diameter of the annular floor section corresponds to the inner diameter of the cylindrical inner wall.

14. The device according to claim 1, wherein the floor section (30) has an arched base that is arched radially inward from the reaction chamber.
